(19) United States
(12) Patent Application Publication
(10) Pub. No.: US 2022/0077137 A1
(43) Pub. Date: Mar. 10, 2022

(54) SEMICONDUCTOR DEVICE

(71) Applicant: SOCIONEXT INC., Kanagawa (JP)

(72) Inventors: Hidetoshi TANAKA, Yokohama (JP); Mai Tsukamoto, Yokohama (JP)

(21) Appl. No.: 17/467,069

(22) Filed: Sep. 3, 2021

(30) Foreign Application Priority Data
Sep. 9, 2020 (JP) 2020-151424

(51) Int. Cl. H01L 27/02; H01L 23/522

(52) U.S. Cl. CPC H01L 27/0255; H01L 27/0266; H01L 27/0292; H01L 23/5226

(57) ABSTRACT

A semiconductor device includes a pad portion, a protection circuit, N wiring layers, and conductive vias connecting adjacent wiring layers, wherein, in a plan view, the semiconductor device includes a first area, a second area, and a third area, wherein the N wiring layers are provided to extend over the first area, the second area, and the third area, wherein a first wiring layer on a side of the pad portion is connected to the pad portion in the first area, and wherein an N-th wiring layer on a side of the protection circuit is connected to the protection circuit in the second area, and in the second area and the third area, where a total cross-sectional area of i-th conductive vias connecting an i-th wiring layer and an (i+1)-th wiring layer is denoted as Sᵢ, S₁ is smaller than Sⱼ for any j (j being 2 or more).

### CROSS-REFERENCE TO RELATED APPLICATION

The present application claims priority to Japanese Patent Application No. 2020-151424, filed on Sep. 9, 2020, which is incorporated herein by reference in its entirety.

### FIELD

The present disclosure relates to a semiconductor device.

### BACKGROUND

A semiconductor device including an electrode pad and a protection circuit for protecting an internal circuit from an electro-static discharge (ESD) is known.

### SUMMARY

A semiconductor device according to the present disclosure includes:
a pad portion;
a protection circuit provided apart from the pad portion in a plan view;
N wiring layers stacked between the protection circuit and the pad portion, N being an integer of 2 or more, the N wiring layers connecting the pad portion and the protection circuit; and
a plurality of conductive vias connecting wiring layers adjacent to each other in a stacking direction among the N wiring layers,
wherein, in a plan view, the semiconductor device comprises:
a first area;
a second area; and
a third area connecting the first area and the second area,
wherein the N wiring layers are provided to extend over the first area, the second area, and the third area,
wherein, among the N wiring layers, a first wiring layer from the pad portion in the stacking direction is connected to the pad portion in the first area,
wherein, among the N wiring layers, an N-th wiring layer from the pad portion in the stacking direction is connected to the protection circuit in the second area, and
in the second area and the third area, where a total cross-sectional area of i-th conductive vias connecting an i-th wiring layer and an (i+1)-th wiring layer from the pad portion in the stacking direction among the N wiring layers is denoted as Sᵢ, i being an integer equal to or more than 1 and equal to or less than (N−1), a total cross-sectional area S₁ is smaller than a total cross-sectional area Sⱼ for any j, j being an integer equal to or more than 2 and equal to or less than (N−1).

The object and advantages of the invention will be realized and attained by means of the elements and combinations particularly pointed out in the claims. It is to be understood that both the foregoing general description and the following detailed description are exemplary and explanatory and are not restrictive of the invention.

### BRIEF DESCRIPTION OF DRAWINGS

FIG. 1 is a drawing illustrating a layout of a semiconductor device according to a first embodiment;

FIG. 2 is a circuit diagram illustrating a configuration of an input-and-output cell area included in the semiconductor device according to the first embodiment;

FIG. 3 is a drawing illustrating a layout of the input-and-output cell area;

FIG. 4 is a cross sectional view illustrating a configuration of the input-and-output cell area according to the first embodiment;

FIG. 5 is a schematic diagram illustrating a positional relationship of a wiring layer, an input-and-output pad, and a protection circuit according to the first embodiment;

FIG. 6 is a schematic diagram illustrating an example of a planar configuration of diodes;

FIG. 7 is a schematic diagram illustrating a positional relationship between a wiring layer, an input-and-output pad, and a protection circuit in a semiconductor device according to a second embodiment;

FIG. 8 is a schematic diagram illustrating a positional relationship between a wiring layer, an input-and-output pad, and a protection circuit in a semiconductor device according to a third embodiment;

FIG. 9 is a schematic diagram illustrating a positional relationship between a wiring layer, an input-and-output pad, and a protection circuit in a semiconductor device according to a fourth embodiment;

FIG. 10 is a schematic diagram illustrating a positional relationship between a wiring layer, an input-and-output pad, and a protection circuit in a semiconductor device according to a fifth embodiment;

FIG. 11 is a schematic diagram illustrating signal lines in a semiconductor device according to a sixth embodiment;

FIG. 12 is a schematic diagram illustrating a positional relationship between a wiring layer, an input-and-output pad, and a protection circuit in a semiconductor device according to a seventh embodiment; and

FIG. 13 is a circuit diagram illustrating an example of a circuit to which the present disclosure can be applied.

### DESCRIPTION OF EMBODIMENTS

A semiconductor device including an electrode pad and a protection circuit for protecting an internal circuit from an electro-static discharge (ESD) is known, as disclosed in, for example, Japanese Laid-open Patent Publication No. 2014-236044, Japanese Laid-open Patent Publication No. 2018-200916, Japanese Laid-open Patent Publication No. 2018-195775, Japanese Laid-open Patent Publication No. 2013-120797, and Japanese Laid-open Patent Publication No. 2007-250965.

In a conventional semiconductor device, due to the reduction in the size of wirings, even if a protection circuit is provided, a wiring layer between the electrode pad and the protection circuit may become damaged when static electricity is input to the electrode pads.

Accordingly, it is desired to provide a semiconductor device capable of reducing damage of a wiring layer.

Hereinafter, embodiments are specifically described with reference to the attached drawings. In the specification and the drawings of the present application, constituent elements having substantially the same functional configurations may be denoted by the same reference numerals, and redundant explanations thereabout may be omitted. In the following explanation, the two directions that are parallel to the surface of the substrate and that are orthogonal to each other are referred to as the X direction and the Y direction, and the direction perpendicular to the surface of the substrate is referred to as the Z direction.

### First Embodiment

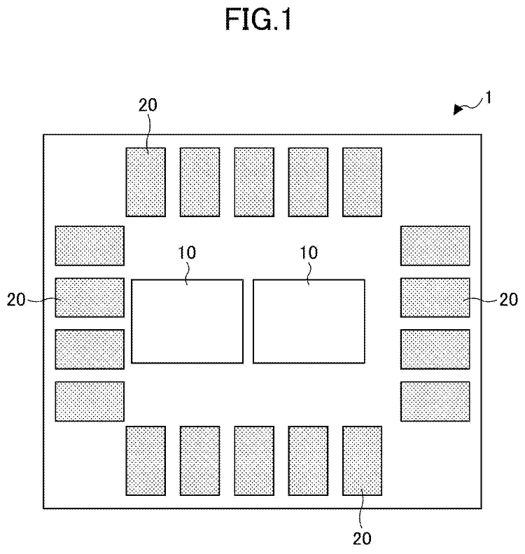

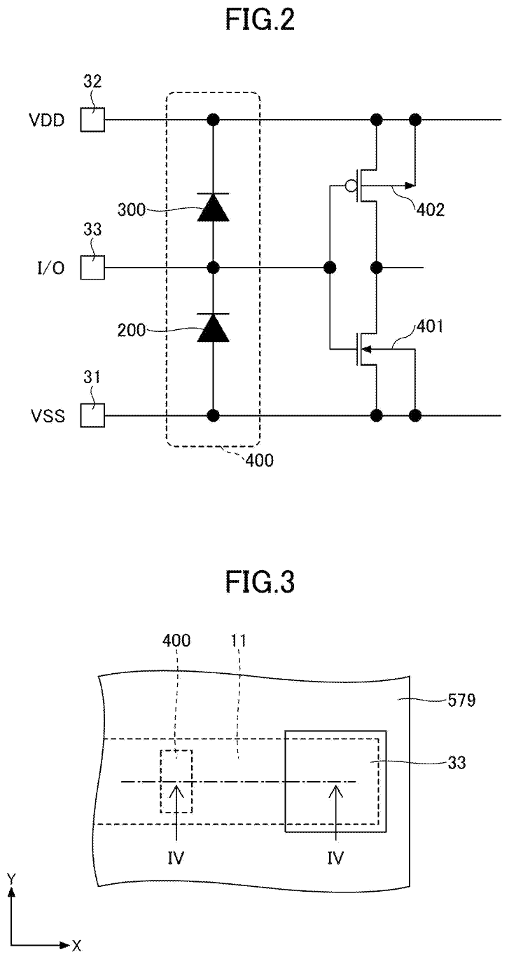

First, the first embodiment is explained. FIG. 1 is a drawing illustrating a layout of a semiconductor device according to the first embodiment. FIG. 2 is a circuit diagram illustrating a configuration of an input-and-output cell area included in the semiconductor device according to the first embodiment. FIG. 3 is a drawing illustrating a layout of an input-and-output cell area.

As illustrated in FIG. 1, the semiconductor device 1 according to the first embodiment includes multiple internal circuit areas 10 and input-and-output (I/O) cell areas 20 arranged around the multiple internal circuit areas 10. Alternatively, the semiconductor device 1 may include a single internal circuit area 10, or may include three or more internal circuit areas 10.

As illustrated in FIG. 2, the I/O cell area 20 includes a VSS pad 31, a VDD pad 32, and an I/O pad 33. A VSS wiring for supplying VSS power supply potential to the internal circuit area 10 is connected to the VSS pad 31. The VSS power supply potential is, for example, a ground potential. A VDD wiring for supplying VDD power supply potential to the internal circuit area 10 is connected to the VDD pad 32. A signal line of the internal circuit area 10 is connected to the I/O pad 33. The I/O cell area 20 includes, for example, an inverter including an N channel MOS transistor 401 and a P channel MOS transistor 402. For example, the gate of the N channel MOS transistor 401 and the gate of the P channel MOS transistor 402 are connected to the I/O pad 33. For example, the source of the N channel MOS transistor 401 is connected to the VSS pad 31, and the source of the P channel MOS transistor 402 is connected to the VDD pad 32. The VSS wiring may be referred to as a ground wiring, and the VDD wiring may be referred to as a power supply wiring.

As illustrated in FIG. 2, the I/O cell area 20 includes a protection circuit 400 including a diode 200 and a diode 300. The anode of the diode 200 is connected to the VSS pad 31, and the cathode of the diode 200 is connected to the I/O pad 33. The anode of the diode 300 is connected to the I/O pad 33, and the cathode of the diode 300 is connected to the VDD pad 32.

As illustrated in FIG. 3, the I/O pad 33 is provided to be exposed from a passivation film 579, and the protection circuit 400 is covered with the passivation film 579. In a plan view, the protection circuit 400 is provided at a position apart from the I/O pad 33. A signal line 11 of the internal circuit area 10 is connected to the I/O pad 33, and the protection circuit 400 is connected to the signal line 11.

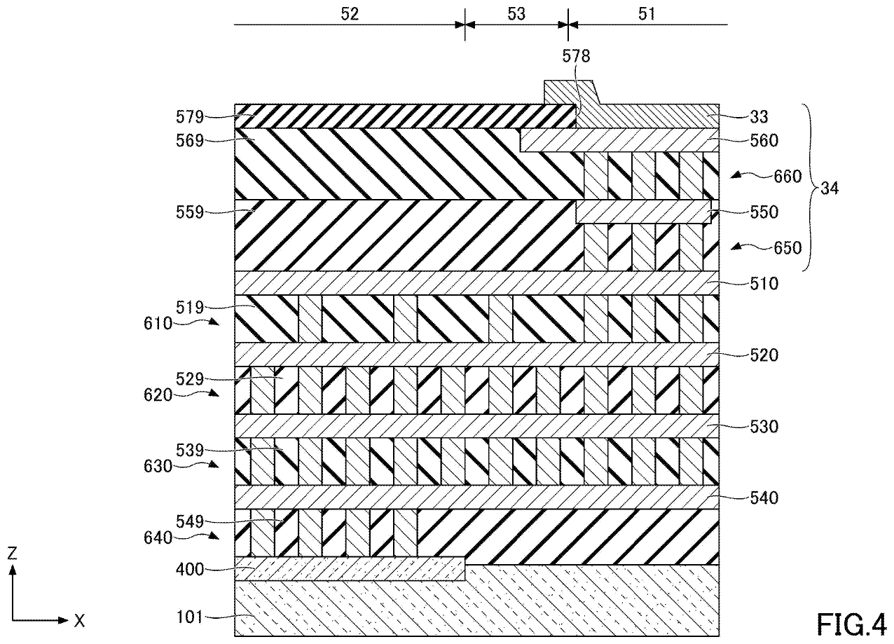

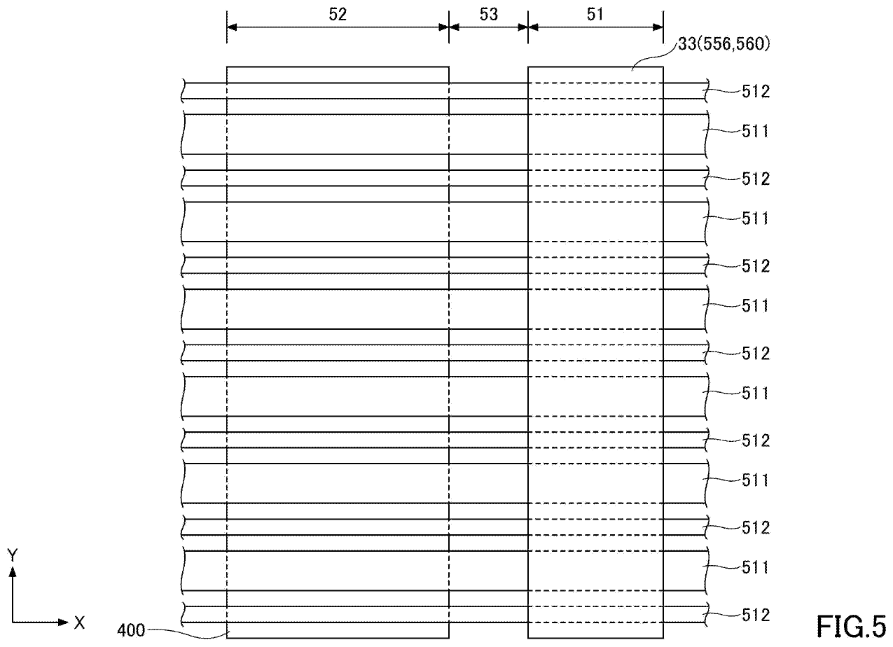

Next, the I/O cell area 20 according to the first embodiment is explained in detail. FIG. 4 is a cross sectional view illustrating the configuration of the I/O cell area 20 according to the first embodiment. FIG. 5 is a schematic diagram illustrating a positional relationship between a wiring layer, an I/O pad, and a protection circuit according to the first embodiment. FIG. 4 corresponds to a cross-sectional view taken along line IV-IV of FIG. 3.

As illustrated in FIG. 4 and FIG. 5, the protection circuit 400 is arranged at a position apart from the I/O pad 33 in a plan view. In the plan view, the I/O cell area 20 includes a first area 51, a second area 52, and a third area 53 connecting the first area 51 and the second area 52.

As illustrated in FIG. 4, the protection circuit 400 is formed on the surface of the substrate 101. An insulating film 549 is provided to cover the protection circuit 400, and a fourth wiring layer 540 is formed on the surface of the insulating film 549. The fourth wiring layer 540 is formed to extend over the first area 51, the second area 52, and the third area 53. The insulating film 549 is provided with multiple conductive vias 640 connecting the fourth wiring layer 540 and the protection circuit 400. The conductive vias 640 are formed in the second area 52. In the second area 52, the fourth wiring layer 540 is connected to the protection circuit 400.

An insulating film 539 is formed to cover a fourth wiring layer 540, and a third wiring layer 530 is formed on the surface of the insulating film 539. In the insulating film 539, multiple conductive vias 630 are provided to connect the third wiring layer 530 and the fourth wiring layer 540. An insulating film 529 is formed to cover a third wiring layer 530, and a second wiring layer 520 is formed on the surface of the insulating film 529. In the insulating film 529, multiple conductive vias 620 are provided to connect the second wiring layer 520 and the third wiring layer 530. An insulating film 519 is formed to cover a second wiring layer 520, and the first wiring layer 510 is formed on the surface of the insulating film 519. In the insulating film 519, multiple conductive vias 610 are provided to connect the first wiring layer 510 and the second wiring layer 520. The first wiring layer 510, the third wiring layer 530, and the second wiring layer 520 are formed to extend over the first area 51, the third area 53, and the second area 52. The conductive vias 610, 630, and 620 are also provided along the first area 51, the third area 53, and the second area 52.

An insulating film 559 is formed to cover a first wiring layer 510, and a second pad contact layer 550 is formed on the surface of the insulating film 559. Multiple conductive vias 650 connecting the second pad contact layer 550 and the first wiring layer 510 are provided in the insulating film 559. An insulating film 569 is formed to cover the second pad contact layer 550, and the first pad contact layer 560 is formed on the surface of the insulating film 569. Multiple conductive vias 660 connecting the first pad contact layer 560 and the second pad contact layer 550 are provided in the insulating film 569. The second pad contact layer 550 and the first pad contact layer 560 are formed in the first area 51. The conductive vias 650 and the conductive vias 660 are also formed in the first area 51.

The passivation film 579 is provided to cover the sixth wiring layer and the insulating film 569. In the passivation film 579, an opening 578 for exposing a portion of the first pad contact layer 560 is formed. The I/O pad 33 is provided on the inside of the opening 578. The I/O pad 33, the first pad contact layer 560, the conductive vias 660, the second pad contact layer 550, and the conductive vias 650 are included in the pad portion 34. The first wiring layer 510 is connected to the pad portion 34 in the first area 51.

In the first area 51, the total cross-sectional area of the conductive vias 610, the total cross-sectional area of the conductive vias 620, and the total cross-sectional area of the conductive vias 630 are equal. In contrast, in the second area 52 and the third area 53, the total cross-sectional area S₁ of the conductive vias 610 is smaller than the total cross-sectional area S₂ of the conductive vias 620 and smaller than the total cross-sectional area S₃ of the conductive vias 630. For example, the diameter and the cross-sectional area of each of the conductive vias 610, the conductive vias 620, and the conductive vias 630 is equal, and in the second area 52 and the third area 53, the total number A₁ of the conductive vias 610 is smaller than the total number A₂ of the conductive vias 620 and smaller than the total number A₃ of the conductive via 630. In the present disclosure, the cross-sectional area of a conductive via is a cross-sectional area on a plane parallel to the principal surface of the substrate in which the conductive vias are provided. Specifically, the cross-sectional area of a conductive via is a cross-sectional area on a plane perpendicular to the height direction (i.e., the thickness direction or the stacking direction) of the semiconductor device 1. In a case where the cross-sectional area of a conductive via changes in the height direction, the cross-sectional area of a conductive via is defined as a cross-sectional area at a portion where the diameter is the smallest. It is to be understood that the sizes of cross-sectional areas are deemed to be the same, even when the diameters and the cross-sectional areas of the conductive vias are different due to manufacturing variation. Also, the total cross-sectional areas are deemed to be the same, even when the summations of the cross-sectional areas of the manufactured conductive vias are different due to difference in the cross-sectional areas of the conductive vias in respective layers. The diameters and the cross-sectional areas of the conductive vias 610, the conductive vias 620, and the conductive vias 630 may be different from each other.

As illustrated in FIG. 5, the first wiring layer 510 includes signal lines 511 and power supply lines 512. The power supply line 512 is connected to, for example, the VSS pad 31 or the VDD pad 32. The signal line 511 is connected to the I/O pad 33 via the conductive vias 650, the second pad contact layer 550, the conductive vias 660, and the first pad contact layer 560. In FIG. 5, although hidden by the signal line 511, signal lines of the same width as the signal line 511 are also provided in the second wiring layer 520, the third wiring layer 530, and the fourth wiring layer 540. These signal lines constitute the signal line 11 (see FIG. 3). In FIG. 5, although hidden by the power supply line 512, signal lines of the same width as the power supply line 512 are also provided in the second wiring layer 520, the third wiring layer 530, and the fourth wiring layer 540. Wirings are deemed to be of the same width, even when the widths of the wirings are different due to manufacturing variations.

In the first embodiment, in the second area 52 and the third area 53, the electric resistance between the first wiring layer 510 and the second wiring layer 520 is higher than the electric resistance between the second wiring layer 520 and the third wiring layer 530, and is higher than the electric resistance between the third wiring layer 530 and the fourth wiring layer 540. In the first area 51, the electric resistance between the first wiring layer 510 and the second wiring layer 520, the electric resistance between the second wiring layer 520 and the third wiring layer 530, and the electric resistance between the third wiring layer 530 and the fourth wiring layer 540 are the same as one another. Therefore, as compared with the case where the total cross-sectional area S₁ of the conductive vias 610 is the same as the total cross-sectional area S₂ of the conductive vias 620 and the total cross-sectional area S₃ of the conductive vias 630, the ESD current flowing to the I/O pad 33 is more likely to flow to the second wiring layer 520 and the third wiring layer 530. Therefore, the concentration of the ESD current to the first wiring layer 510 can be alleviated, and thus the first wiring layer 510 can be protected from being damaged.

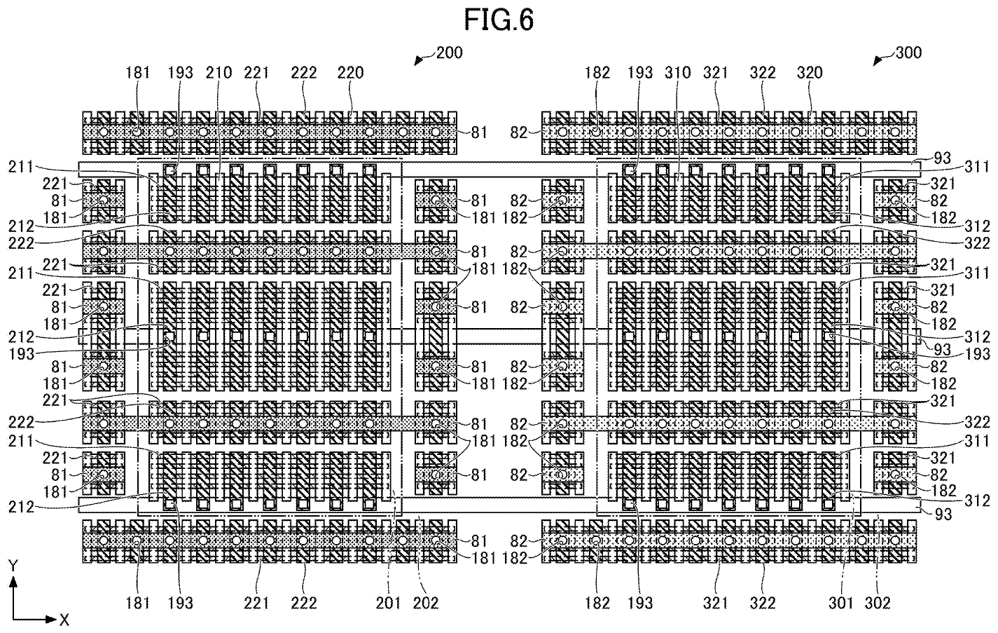

Hereinafter, an example of diodes 200 and 300 is explained. FIG. 6 is a schematic diagram illustrating an example of a planar configuration of the diodes 200 and 300.

As illustrated in FIG. 6, the diode 200 and the diode 300 are arranged in the X direction. Multiple signal lines 93 (three signal lines 93 in this example) are provided commonly for the diode 200 and the diode 300.

The diode 200 includes a main portion 201 and a guard ring portion 202 surrounding the main portion 201 in a plan view.

In the main portion 201, four N-type fins 211, four P-type fins 221, and four N-type fins 211 are provided in this order between two signal lines 93 adjacent to each other in the Y direction. In this manner, three signal lines 93 are provided. Therefore, the main portion 201 includes two sets of fins, each set including the four N-type fins 211, the four P-type fins 221, and the four N-type fins 211. In addition, the main portion 201 includes local interconnects 212 and 222, quasi-gate electrodes 210 and 220, contact holes 193 and 181, and power supply wirings 81.

In the guard ring portion 202, multiple P-type fins 221 are arranged in a ring form. The guard ring portion 202 includes local interconnects 222 connected to P-type fins 221 and power supply wirings 81 connected to local interconnects 222. Some of the power supply wirings 81 in the guard ring portion 202 may be commonly used for some of the power supply wirings 81 in the main portion 201.

The diode 300 includes a main portion 301 and a guard ring portion 302 surrounding the main portion 301 in a plan view.

In the main portion 301, four P-type fins 311, four N-type fins 321, and four P-type fins 311 are provided in this order between two signal lines 93 adjacent to each other in the Y direction. In this manner, three signal lines 93 are provided. Therefore, the main portion 301 includes two sets of fins, each set including the four P-type fins 311, the four N-type fins 321, and the four P-type fins 311. In addition, the main portion 301 includes similarly to the first embodiment, local interconnects 312 and 322, quasi-gate electrodes 310 and 320, contact holes 193 and 182, and power supply wirings 82.

In the guard ring portion 302, multiple N-type fins 321 are arranged in a ring form. The guard ring portion 302 includes local interconnects 322 connected to N-type fins 321 and power supply wirings 82 connected to local interconnects 322. Some of the power supply wirings 82 in the guard ring portion 302 may be commonly used for some of the power supply wirings 82 in the main portion 301.

For example, the signal lines 93 are connected to the I/O pads 33 via the signal lines 11 (see FIG. 3). The diode 200 includes the guard ring portion 202, and the diode 300 includes the guard ring portion 302, so that leakage of currents from the main portions 201 and 301 to the outside can be alleviated.

The diodes 200 and 300 do not have to include fins, and may be planar-type diodes or the like. Instead of the diodes 200 and 300, the protection circuit 400 may include transistors.

### Second Embodiment

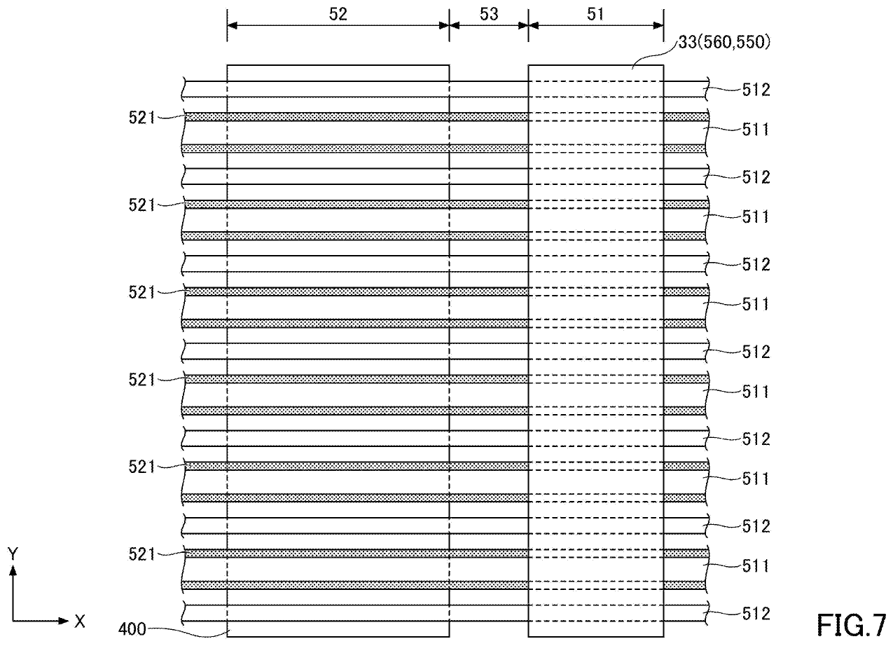

Next, the second embodiment is explained. FIG. 7 is a schematic diagram illustrating a positional relationship between a wiring layer, an I/O pad, and a protection circuit in a semiconductor device according to the second embodiment.

In the second embodiment, as illustrated in FIG. 7, the signal lines 511 included in the first wiring layer 510 are narrower than the signal lines 521 included in the second wiring layer 520. In FIG. 7, although hidden by the signal line 521, signal lines of the same width as the signal line 521 are also provided in the third wiring layer 530 and the fourth wiring layer 540.

Other than the above, the second embodiment is substantially the same as the first embodiment.

In the second embodiment, in the second area 52 and the third area 53, the electric resistance between the first wiring layer 510 and the second wiring layer 520 is higher than the electric resistance between the second wiring layer 520 and the third wiring layer 530 and the electric resistance between the third wiring layer 530 and the fourth wiring layer 540, even more than the first embodiment. Therefore, the ESD current flowing to the I/O pad 33 is more likely to flow to the second wiring layer 520 and the third wiring layer 530. Therefore, the concentration of the ESD current to the first wiring layer 510 can be more effectively alleviated, and the first wiring layer 510 is more effectively protected from being damaged.

### Third Embodiment

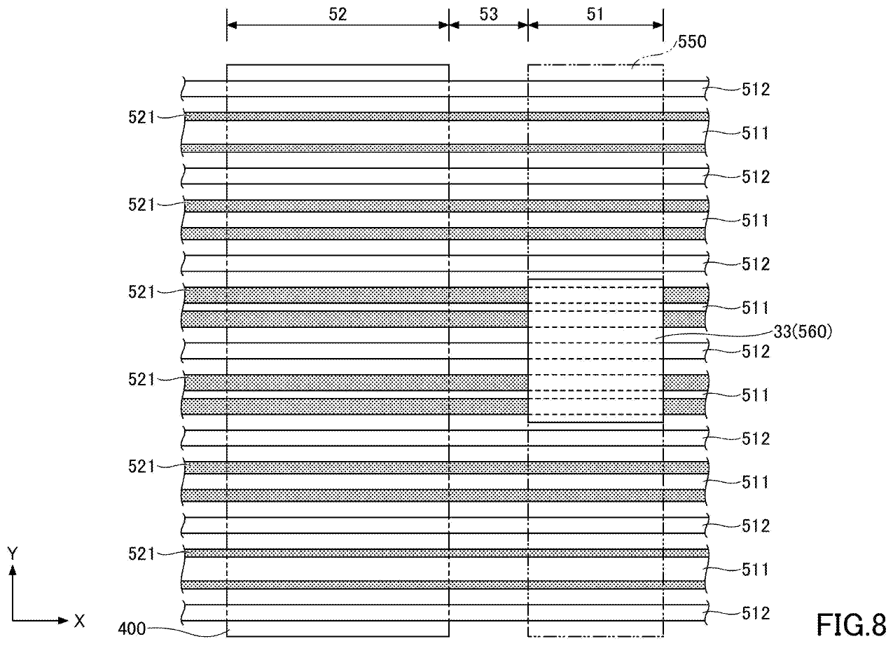

Next, the third embodiment is explained. FIG. 8 is a schematic diagram illustrating a positional relationship between a wiring layer, an I/O pad, and a protection circuit in a semiconductor device according to the third embodiment.

In the third embodiment, as illustrated in FIG. 8, the size of the I/O pad 33 in the Y direction is less than the size of the second pad contact layer 550 in the Y direction. In the plan view, the first pad contact layer 560 is provided in the same range as the I/O pad 33, and in the Y direction, the first pad contact layer 560 overlaps with only a portion of the second pad contact layer 550. The number of the signal lines 511 that overlap with the first pad contact layer 560 in a plan view is less than the number of the signal lines 511 that overlap with the second pad contact layer 550 in a plan view. The signal lines 511 that overlap with the first pad contact layer 560 in a plan view are narrower than the signal lines 511 that do not overlap with the first pad contact layer 560 in a plan view. In the plan view, among the multiple signal lines 511 that do not overlap with the first pad contact layer 560, signal lines 511 located closer to the first pad contact layer 560 are narrower.

Other than the above, the third embodiment is substantially the same as the second embodiment.

In the third embodiment, among the multiple signal lines 511, signal lines 511 located closer to the first pad contact layer 560 are narrower in a plan view. Therefore, among the multiple signal lines 511, the concentration of the ESD current to the signal lines 511 and the like that overlap with the first pad contact layer 560 in a plan view can be more effectively alleviated, and thus the first wiring layer 510 can be more effectively protected from being damaged.

### Fourth Embodiment

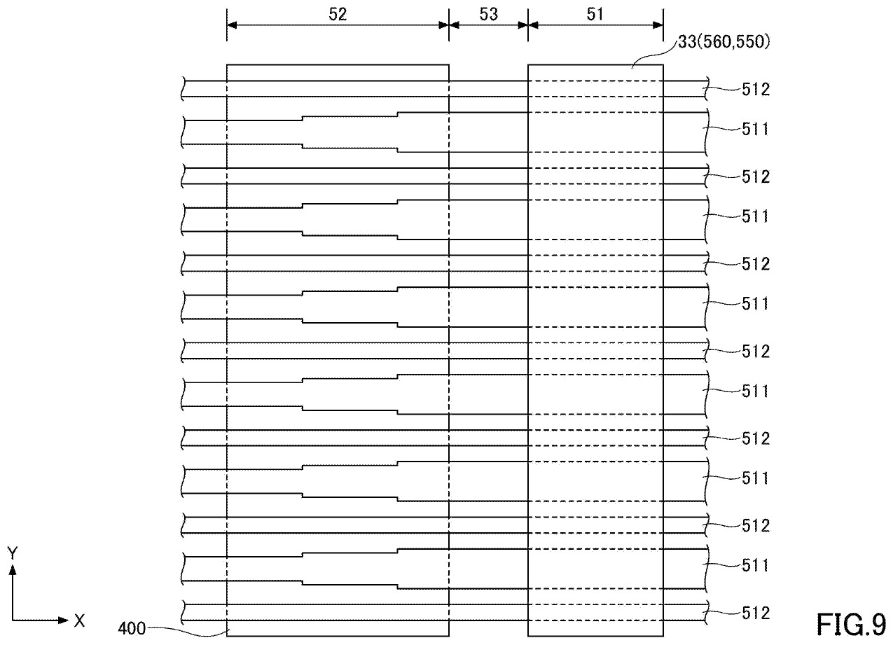

Next, the fourth embodiment is explained. FIG. 9 is a schematic diagram illustrating a positional relationship between a wiring layer, an I/O pad, and a protection circuit in a semiconductor device according to the fourth embodiment.

In the fourth embodiment, as illustrated in FIG. 9, the signal lines 511 included in the first wiring layer 510 are narrower in the second area 52 than in the first area 51. The widths of the signal lines 511 change in multiple steps (in two steps in the fourth embodiment) in the direction in which the signal lines 511 extend. In FIG. 9, although hidden by the signal line 511, signal lines of the same width as the signal line 511 are also provided in the second wiring layer 520, the third wiring layer 530, and the fourth wiring layer 540.

Other than the above, the second embodiment is substantially the same as the first embodiment.

Effects similar to those achieved by the first embodiment can be achieved by the fourth embodiment. When the first wiring layer 510, the second wiring layer 520, the third wiring layer 530, and the fourth wiring layer 540 are formed, chemical mechanical polishing (CMP) may be performed, and therefore, the thicknesses can be readily adjusted in a uniform manner during the CMP.

The widths of signals lines in only the first wiring layer 510 may be changed, and the second wiring layer 520, the third wiring layer 530, and the fourth wiring layer 540 may be kept at the same width in a manner similar to the first embodiment.

### Fifth Embodiment

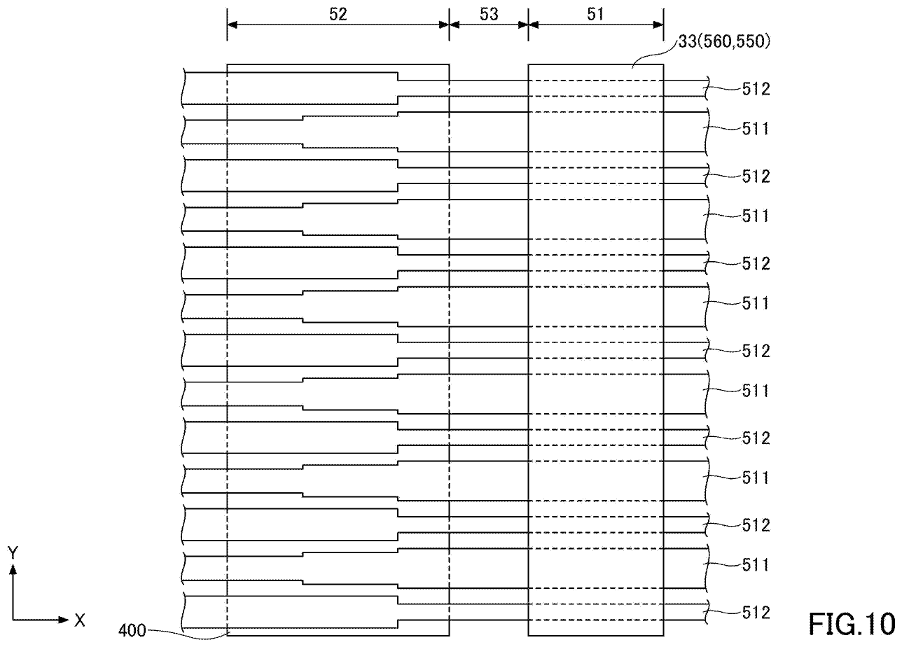

Next, the fifth embodiment is explained. FIG. 10 is a schematic diagram illustrating a positional relationship between a wiring layer, an I/O pad, and a protection circuit in a semiconductor device according to the fifth embodiment.

In the fifth embodiment, as illustrated in FIG. 10, the power supply lines 512 included in the first wiring layer 510 are thicker in the second area 52 than in the first area 51. In FIG. 10, although hidden by the power supply line 512, signal lines of the same width as the power supply line 512 are also provided in the second wiring layer 520, the third wiring layer 530, and the fourth wiring layer 540.

Other than the above, the fifth embodiment is substantially the same as the fourth embodiment.

The fifth embodiment can provide substantially the same effects as those in the fourth embodiment.

### Sixth Embodiment

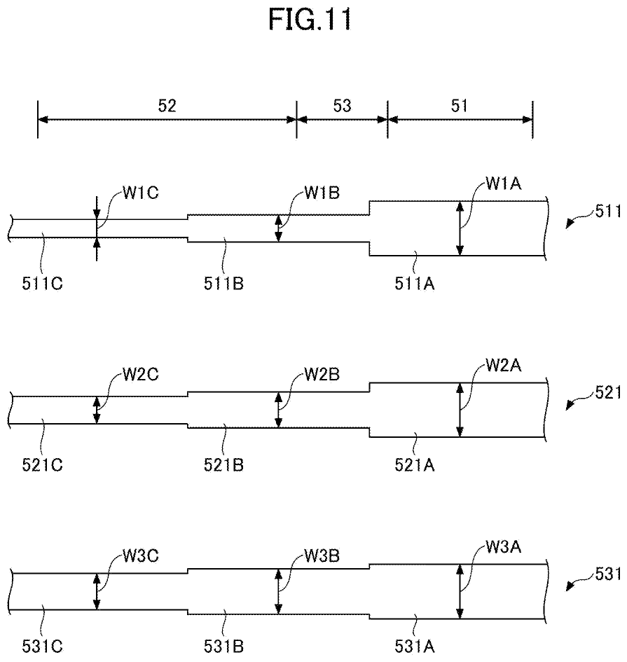

Next, the sixth embodiment is explained. FIG. 11 is a schematic diagram illustrating signal lines in a semiconductor device according to the sixth embodiment.

In the sixth embodiment, as illustrated in FIG. 11, the widths of the signal lines 511 included in the first wiring layer 510 change so as to decrease in two steps in the third area 53 and the second area 52. Likewise, the widths of the signal lines 521 included in the second wiring layer 520 change so as to decrease in two steps in the third area 53 and the second area 52, and the widths of the signal lines 531 included in the third wiring layer 530 change so as to decrease in two steps in the third area 53 and the second area 52.

The signal line 511 includes a first portion 511A of which the width is W1A, a second portion 511B of which the width is W1B, and a third portion 511C of which the width is W1C. The width W1A is larger than the width W1B, and the width W1B is larger than the width W1C. The second portion 511B is located between the first portion 511A and the third portion 511C.

The signal line 521 includes a first portion 521A of which the width is W2A, a second portion 521B of which the width is W2B, and a third portion 521C of which the width is W2C. The width W2A is larger than the width W2B, and the width W2B is larger than the width W2C. The second portion 521B is located between the first portion 521A and the third portion 521C.

The signal line 531 includes a first portion 531A of which the width is W3A, a second portion 531B of which the width is W3B, and a third portion 531C of which the width is W3C. The width W3A is larger than the width W3B, and the width W3B is larger than the width W3C. The second portion 531B is located between the first portion 531A and the third portion 531C.

In the plan view, the first portion 511A, 521A, and 531A overlap with one another. The widths W1A, W2A, and W3A are the same. In the plan view, the second portions 511B, 521B, and 531B overlap with one another. The width W1B is smaller than the width W2B, and the width W2B is smaller than the width W3B. In the plan view, the third portions 511C, 521C, and 531C overlap with one another. The width W1C is smaller than the width W2C, and the width W2C is smaller than the width W3C.

In this manner, in the sixth embodiment, the widths of the signal lines 511 to 531 decrease apart from the first area 51, and in the stacking direction, the widths of the signal lines 511 to 531 increase apart from the pad portion 34 toward the protection circuit 400.

Other than the above, the sixth embodiment is substantially the same as the first embodiment.

The sixth embodiment can provide substantially the same effects as those in the second embodiment and to the fourth embodiment.

### Seventh Embodiment

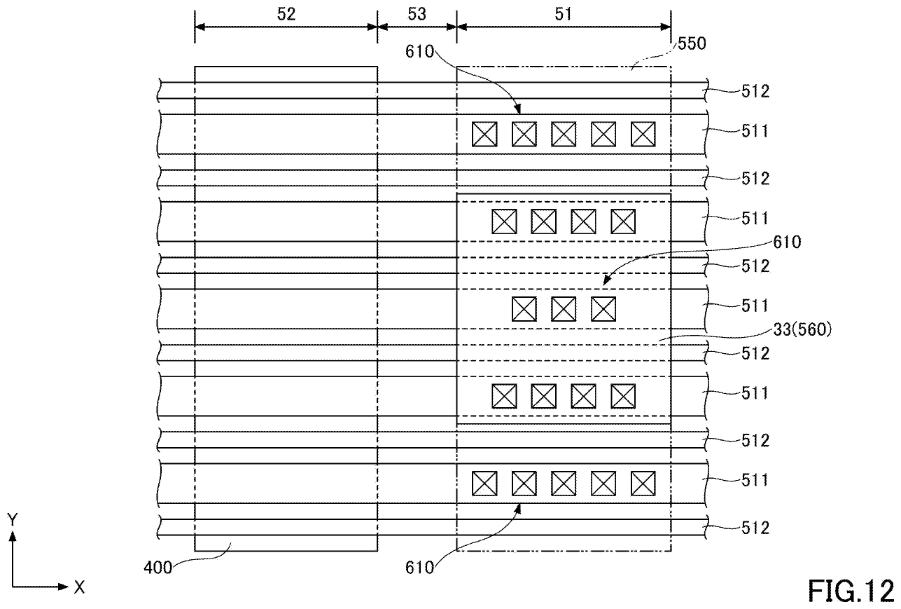

Next, the seventh embodiment is explained. FIG. 12 is a schematic diagram illustrating a positional relationship between a wiring layer, an I/O pad, and a protection circuit in a semiconductor device according to the seventh embodiment.

In the seventh embodiment, as illustrated in FIG. 12, the size of the I/O pad 33 in the Y direction is less than the size of the second pad contact layer 550 in the Y direction. In the plan view, the first pad contact layer 560 is provided in the same range as the I/O pad 33, and in the Y direction, the first pad contact layer 560 overlaps with only a portion of the second pad contact layer 550. The number of the signal lines 511 that overlap with the first pad contact layer 560 in a plan view is less than the signal lines 511 that overlap with the second pad contact layer 550 in a plan view. The number of conductive vias 610 decrease toward the center in the Y direction in a range that overlaps with the first pad contact layer 560.

Other than the above, the seventh embodiment is substantially the same as the first embodiment.

In the seventh embodiment, in the first area 51, the electric resistance between the first wiring layer 510 and the second wiring layer 520 increases toward the center in the Y direction in the range that overlaps with the first pad contact layer 560. Therefore, the ESD current flowing to the I/O pad 33 is more likely to flow to signal lines 511 apart from the center in the Y direction in the range that overlaps with the first pad contact layer 560. Therefore, the concentration of the ESD current to particular signal lines 511 can be more effectively alleviated, and thus the first wiring layer 510 can be more effectively protected from being damaged.

In any of the embodiments, the number of wiring layers and the number of pad contact layers are not limited.

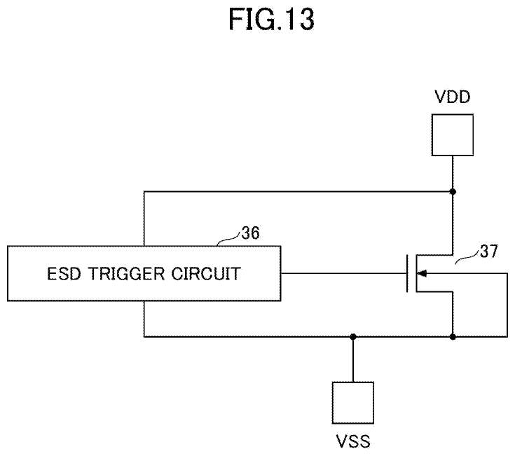

An electrode pad to which the protection circuit is connected is not limited to the I/O pad. For example, as illustrated in FIG. 13, in a semiconductor device in which an ESD trigger circuit 36 and an N channel MOS transistor 37 serving as a protection circuit are connected in parallel between a VSS pad 31 and a VDD pad 32, the configuration of any of the embodiments may be applied to a portion between the VSS pad 31 and the transistor 37 or between the VDD pad 32 and the transistor 37.

According to the present disclosure, it is possible to reduce damage of a wiring layer.

Although the present invention has been described above with reference to the embodiments, the present invention is not limited to the features described in the embodiments. These features can be changed without departing from the scope of the claimed subject matter, and can be appropriately determined according to the implementation to which the present invention is applied.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A semiconductor device comprising:
a pad portion;
a protection circuit provided apart from the pad portion in a plan view;
N wiring layers stacked between the protection circuit and the pad portion, N being an integer of 2 or more, the N wiring layers connecting the pad portion and the protection circuit; and
a plurality of conductive vias connecting wiring layers adjacent to each other in a stacking direction among the N wiring layers,
wherein, in a plan view, the semiconductor device comprises:
a first area;
a second area; and
a third area connecting the first area and the second area,
wherein the N wiring layers are provided to extend over the first area, the second area, and the third area,
wherein, among the N wiring layers, a first wiring layer from the pad portion in the stacking direction is connected to the pad portion in the first area,
wherein, among the N wiring layers, an N-th wiring layer from the pad portion in the stacking direction is connected to the protection circuit in the second area, and
in the second area and the third area, where a total cross-sectional area of i-th conductive vias connecting an i-th wiring layer and an (i+1)-th wiring layer from the pad portion in the stacking direction among the N wiring layers is denoted as Sᵢ, i being an integer equal to or more than 1 and equal to or less than (N−1), a total cross-sectional area S₁ is smaller than a total cross-sectional area Sⱼ for any j, j being an integer equal to or more than 2 and equal to or less than (N−1).

2. The semiconductor device according to claim 1, wherein the plurality of conductive vias have a same diameter as each other, and
in the second area and the third area, where a total number of the i-th conductive vias is denoted as Aᵢ, a total number A₁ is smaller than a total number Aⱼ. 15

3. The semiconductor device according to claim 1, wherein each of the N wiring layers includes signal lines electrically connected to the pad portion and the protection circuit, and
first signal lines included in the first wiring layer among the signal lines are narrower than (i+1)-th signal lines included in the (i+1)-th wiring layer among the signal lines.

4. The semiconductor device according to claim 3, wherein the pad portion includes:
an electrode pad; and
a plurality of pad contact layers provided between the electrode pad and the first wiring layer in the stacking direction,
wherein in a plan view, a first pad contact layer located closest to the electrode pad among the plurality of pad contact layers overlaps, in a direction in which the signal lines are arranged, with a portion of a second pad contact layer located closest to the first wiring layer among the plurality of pad contact layers, and
a first signal line overlapping with the first pad contact layer in a plan view among the first signal lines is narrower than a first signal line not overlapping with the first pad contact layer in a plan view among the first signal lines.

5. The semiconductor device according to claim 4, wherein widths of first signal lines not overlapping with the first pad contact layer in a plan view among the first signal lines decrease toward the first pad contact layer.

6. The semiconductor device according to claim 1, wherein each of the N wiring layers includes signal lines electrically connected to the pad portion and the protection circuit, and
first signal lines included in the first wiring layer among the signal lines are narrower in the second area than in the first area.

7. The semiconductor device according to claim 6, wherein widths of the first signal lines change in a plurality of steps in a direction in which the first signal lines extend.

8. The semiconductor device according to claim 6, wherein (i+1)-th signal lines included in the (i+1)-th wiring layer among the signal lines are narrower in the second area than in the first area.

9. The semiconductor device according to claim 8, wherein widths of the (i+1)-th signal lines change in a plurality of steps in a direction in which the (i+1)-th signal lines extend.

10. The semiconductor device according to claim 9, wherein in a plan view, i-th signal lines included in the i-th wiring layer among the signal lines are narrower than the (i+1)-th signal lines.

11. The semiconductor device according to claim 1, wherein each of the N wiring layers includes signal lines electrically connected to the pad portion and the protection circuit,
wherein the pad portion includes:
an electrode pad; and
a plurality of pad contact layers provided between the electrode pad and the first wiring layer in the stacking direction,
wherein in a plan view, a first pad contact layer located closest to the electrode pad among the plurality of pad contact layers overlaps, in a direction in which the signal lines are arranged, with only a portion of a second pad contact layer located closest to the first wiring layer among the plurality of pad contact layers, and
conductive vias connected to the first wiring layer among the plurality of conductive vias decreases in number toward a portion close to a center, in the direction in which the signal lines are arranged, in a range that overlaps with the first pad contact layer.
